(19) United States
(12) Patent Application Publication
(10) Pub. No.: US 2025/0176135 A1
(43) Pub. Date: May 29, 2025

(54) WATER-COOLING APPARATUS AND LEAKAGE PROCESSING METHOD

(71) Applicant: Lenovo Enterprise Solutions (Singapore) Pte. Ltd., Singapore (SG)

(72) Inventors: Chih Wei WU, Singapore (SG); Chao Yi HUANG, Singapore (SG); Sheng Ming HSIEH, Singapore (SG); Chieh-Chen CHEN, Singapore (SG)

(21) Appl. No.: 18/962,690

(22) Filed: Nov. 27, 2024

(30) Foreign Application Priority Data
Nov. 29, 2023 (CN) 202311632719.2

(51) Int. Cl. H05K 7/20; G01M 3/16

(52) U.S. Cl. CPC H05K 7/20272; G01M 3/165

(57) ABSTRACT

A water-cooling apparatus includes a chassis, a structure assembly, a controller, a tray assembly, and a leakage sensor. The chassis is configured to accommodate at least one tray assembly, power and cooling medium circulation being supplied to the tray assembly through a power supply circuit and a cooling circulation pipeline. The structure assembly is arranged on a front side and a rear side of the tray assembly and configured to fix or release the tray assembly. A direction in which the tray assembly slides after being released is the rear side. The front side is opposite the rear side. A power source of the power supply circuit and a valve of the cooling circulation pipeline of the tray assembly are turned off after the tray assembly is released by the structure assembly.

### CROSS-REFERENCE TO RELATED APPLICATION

The present disclosure claims priority to Chinese Patent Application No. 202311632719.2, filed on Nov. 29, 2023, the entire content of which is incorporated herein by reference.

### TECHNICAL FIELD

The present disclosure is related to the mechanical control technology field and, more particularly, to a water-cooling apparatus and a leakage processing method.

### BACKGROUND

In related technologies, when a water-cooling apparatus leaks, the system sends an alarm message to remind maintenance personnel to deal with the leak. However, the leak is still ongoing. The cooling medium leaked from the water-cooling apparatus cause serious damage to an electronic device, and even cause danger due to short circuits.

### SUMMARY

One aspect of the present disclosure provides a water-cooling apparatus including a chassis, a structure assembly, a controller, a tray assembly, and a leakage sensor. The chassis is configured to accommodate at least one tray assembly, power and cooling medium circulation being supplied to the tray assembly through a power supply circuit and a cooling circulation pipeline. The structure assembly is arranged on a front side and a rear side of the tray assembly and configured to fix or release the tray assembly. A direction in which the tray assembly slides after being released is the rear side. The front side is opposite the rear side. A power source of the power supply circuit and a valve of the cooling circulation pipeline of the tray assembly are turned off after the tray assembly is released by the structure assembly. The controller is connected to the structure assembly and a leakage sensor and configured to issue a signal based on a predetermined operation mode after the leakage sensor detects a leakage. The tray assembly is configured to accommodate a fixed server node and vertically arranged at the chassis. The leakage sensor is connected to the controller, arranged at the chassis and/or the tray assembly to be neighboring to the tray assembly, and configured to detect whether the tray assembly leaks.

Another aspect of the present disclosure provides a leakage processing method. The method includes, in an automatic mode, in response to detecting that a tray assembly leaks, releasing the leaking tray assembly and disconnecting power supply and a cooling circulation pipeline of the leaking tray assembly, and in a manual mode, in response to detecting that the tray assembly leaks, disconnecting the power supply and the cooling circulation pipeline of the leaking tray assembly.

### BRIEF DESCRIPTION OF THE DRAWINGS

FIG. 1 illustrates a schematic structural diagram of a water-cooling apparatus according to some embodiments of the present disclosure.

FIG. 2 illustrates a schematic structural diagram of another water-cooling apparatus according to some embodiments of the present disclosure.

FIG. 3 illustrates a schematic structural diagram of another water-cooling apparatus according to some embodiments of the present disclosure.

FIG. 4 illustrates a schematic structural diagram of another water-cooling apparatus according to some embodiments of the present disclosure.

FIG. 5 illustrates a schematic structural diagram of another water-cooling apparatus according to some embodiments of the present disclosure.

FIG. 6 illustrates a schematic structural diagram of a baffle assembly and an electronic valve according to some embodiments of the present disclosure.

FIG. 7 illustrates a schematic structural diagram of an electromagnetic valve according to some embodiments of the present disclosure.

FIG. 8 illustrates a schematic structural diagram of another water-cooling apparatus according to some embodiments of the present disclosure.

FIG. 9 illustrates a schematic flowchart of a leakage processing method according to some embodiments of the present disclosure.

FIG. 10 illustrates a schematic diagram of a hardware entity of a computer device according to some embodiments of the present disclosure.

### DETAILED DESCRIPTION OF THE EMBODIMENTS

To understand the features and technical contents of embodiments of the present disclosure, implementations of embodiments of the present disclosure are described in detail below in conjunction with the accompanying drawings. The accompanying drawings are merely for reference and description and are not intended to limit embodiments of the present disclosure for illustrative purposes only and are not intended to limit embodiments of the present disclosure.

The terms “first,” “second,” and “third” used in embodiments of the present disclosure are merely for distinguishing similar objects and do not represent a specific order for the objects. When allowed, “first,” “second,” and “third” can be interchangeable in specific orders or sequences. The objects distinguished by “first,” “second,” and “third” can be swapped in appropriate circumstances. Thus, embodiments of the present disclosure can be implemented in an order other than those illustrated or described here.

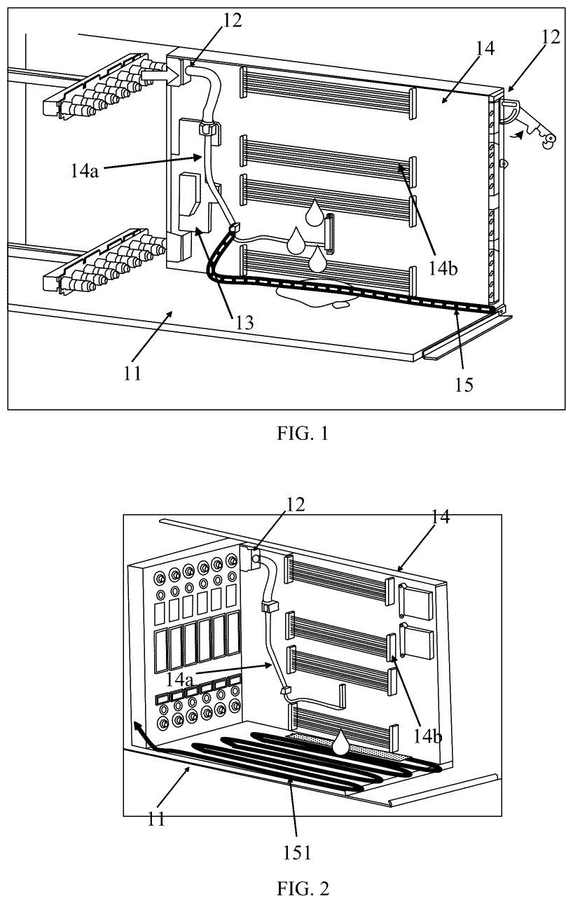

FIG. 1 illustrates a schematic structural diagram of a water-cooling apparatus according to some embodiments of the present disclosure. As shown in FIG. 1, the apparatus includes a chassis 11, a structural assembly 12, a controller 13, and a leakage sensor 15.

The chassis 11 can be configured to accommodate at least one tray assembly. Power and cooling medium circulation can be provided to the tray assembly through a power supply circuit and a cooling circulation pipeline.

In some embodiments, the chassis 11 can include a sliding rail (not shown in the figure), and the tray assembly 14 can be arranged on the sliding rail of the chassis 11. When a plurality of tray assemblies 14 are arranged at the chassis 11, power and cooling medium circulation can be provided to each tray assembly 14 through an individual power supply circuit 14b and an individual cooling circulation pipeline 14a (partially shown in the figure). A part of the power supply circuit 14b and a part of the cooling circulation pipeline 14a on the chassis 11 can be connected to members of the tray assembly through a mechanical structure, such as a plug, a connector, etc. After the tray assembly 14 is ejected, the mechanical structure can be automatically disconnected to cut off the power supply and the cooling medium circulation.

In some embodiments, the chassis 11 can adopt a multi-layer structure, made of both metallic and non-metallic materials. For example, an upper layer can be made of aluminum alloy as a metal member in direct contact with the tray assembly 14. The surface of the aluminum alloy can also be coated with an anti-corrosion coating, while a lower layer can be made of an anti-static material.

The chassis 11 of embodiments of the present disclosure can accommodate the plurality of tray assemblies 14 and provide independent power supply and cooling medium circulation for each tray assembly. The sliding rail can be used to reduce friction between the tray assembly and the chassis to minimize friction between the chassis and the tray assembly. Meanwhile, the chassis 11 can also include other types of low friction structures to allow the tray assembly 14 to be ejected more easily. With the multi-layer structure, the structural strength and reliability of the chassis can be ensured, and the damage to the electronic device due to static electricity can be avoided.

The structural assembly 12 can be arranged at the front side and rear side of the tray assembly 14 and can be configured to fix or release the tray assembly. After the tray assembly 14 is released, the sliding direction can be on the rear side. The front side can correspond to the rear side. After the tray assembly 14 is released by the structural assembly, the power source of the power supply circuit 14b and the valve of the cooling circulation pipeline 14a of the tray assembly 14 can be shut off.

In some embodiments, a plurality of sets of structural assemblies 12 can be provided to fix or release the tray assembly 14 (only one set is shown in FIG. 1). The structural assembly 12 arranged at the front side can eject the tray assembly 14 after the structural assembly 12 at the rear side is unlocked.

In some embodiments, the structural assembly 12 can further include a fixing frame arranged at the back surface of the tray assembly (not shown in the figure). The frame can include a locking structure, which can assist in fixing the tray assembly 14 to prevent the tray assembly 14 from tilting when the tray assembly 14 is properly mounted at the chassis 11.

The structural assembly can be configured to fix the tray assembly 14 and eject the tray assembly 14 after the structural assembly is unlocked to prevent further damage to the electronic device from the leakage.

The controller 13 can be connected to the structural assembly 12 and a leakage sensor 15 and can be configured to send a signal based on a preset operation mode after detecting a leakage via the leakage sensor.

In some embodiments, the controller 13 can be connected to the structural assembly 12 through a mechanical structure, i.e., the controller 13 can be mounted at the structural assembly 12. Meanwhile, the controller 13 can be connected to the leakage sensor 15. When the cooling circulation pipeline 14a at the tray assembly 14 leaks, the cooling liquid can drip onto the leakage sensor 15. The controller 13 can receive the signal from the leakage sensor 15 and subsequently send a signal according to the preset operation mode. The controller 13 can send a signal to the structural assembly 12 to control the structural assembly 12 to unlock the tray assembly 14 or disconnect the power supply and cooling circulation of tray assembly 14.

In some embodiments, each tray assembly 14 can be provided with a corresponding controller. Thus, an individual operation mode can be set for each controller. In some other embodiments, a center controller can be provided and connected to the controller of each tray assembly to set the preset operation mode for the controller of each tray assembly.

In some embodiments, the controller 13 can also include a buzzer. After receiving the signal from the leakage sensor, the controller 13 can send a warning signal and activate the buzzer. Meanwhile, the controller 13 and the tray assembly 14 may be provided with power through different power supply circuits. The controller 13 can include an independent power supply circuit or can be supplied power using the battery.

The controller 13 can receive the signal from the leakage sensor 15 and send the signal determined based on the preset operation mode to the structural assembly 12 after the leakage sensor 15 detects the leakage to control the structural assembly 12 to take corresponding measure to prevent further damage due to the leakage. Moreover, since the controller 13 does not have the same power source with the tray assembly, the controller 13 can still send warning information and continue sending alert after the power of the tray assembly 14 is cut off due to the leakage.

The tray assembly 14 can be configured to accommodate a fixed server node and vertically arranged on the chassis.

In some embodiments, a roller or a structure corresponding to the sliding rail of the chassis 11 can be arranged on a side of the tray assembly 14 in contact with the chassis 11. Thus, the tray assembly 14 can slide on the chassis 11. Meanwhile, the tray assembly 14 can include the server node. The server node can be provided for the scenario of the water-cooling apparatus of the server. When the server node is applied to other scenarios, the tray assembly 14 can accommodate circuits or core members of other electronic devices.

In some embodiments, the tray assembly 14 can include the cooling circulation pipeline 14a and the power supply circuit 14b. The cooling medium in the cooling circulation pipeline 14a can flow through the server node of the tray assembly 14 to lower the temperature of the server node. The power supply circuit 14b can be configured to provide power to the server node at the tray assembly 14 to ensure the server operates normally. A part of the power supply circuit 14b and a part of the cooling circulation pipeline 14a, i.e., branches, can be arranged at the tray assembly 14, the other part of the power supply circuit 14b and the other part of the cooling circulation pipeline 14a, i.e., main routes, can be arranged at the chassis 11. When the power supply or the cooling medium circulation of any tray assembly 14 is cut off, the operations of the power supply circuit 14b and the operations of the cooling circulation pipelines 14a of other tray assemblies 14 may not be affected.

The power supply circuit 14b and the cooling circulation pipeline 14a at the tray assembly 14 can be disconnected, and the tray assembly 14 can slide along the sliding rail on chassis 11. When a cooling pipeline on a tray assembly leaks, the corresponding tray assembly 14 can be easily handled without affecting the normal operations of other tray assemblies 14.

The leakage sensor 15 can be connected to the controller 13 and arranged at the chassis 11 and/or the tray assembly 14 neighboring to the tray assembly 14 and can be configured to detect whether leakage occurs in the tray assembly 14.

In some embodiments, the leakage sensor 15 can be a rope-type leakage sensor, which works on the principle that water is electrically conductive. When any part of the leakage detection rope comes into contact with water, a sensing wire in the rope may have a situation similar to a short circuit. The leakage sensor 15 can be attached underneath each tray assembly 14 or on the chassis 11. The leakage sensors of varying lengths can be configured to monitor leakage for each tray assembly 14 and the overall server. The leakage sensor mounted independently for each tray assembly 14 can directly determine if the cooling medium leaks at the tray assembly. The leakage sensor 15 for monitoring the overall server can further determine which tray assembly 14 leaks based on the change in the resistance value of the leakage sensor 15. Thus, the leakage location can be determined simultaneously in two methods.

The leakage sensor 15 can be the rope-type sensor, can be easily arranged into narrow spaces, and can be bent to adjust the arrangement of the leakage sensor 15. The leakage sensor 15 can perform leakage detection on the individual tray assembly 14 or the overall server and determine the leakage location. The rope-type sensor can perform leakage detection on a larger area by only increasing the length of the sensor.

In some embodiments, the controller 13 can include a first control configured to determine the tray assembly 14 that leaks based on the leakage sensor. The first controller can be further configured to shut off the valves of the cooling circulation pipeline and the power source of the power supply circuit when the leakage is detected in a manual mode. The first controller can be further configured to control the structural assembly corresponding to the tray assembly that leaks to release the tray assembly that leaks when the leakage is detected in the automatic mode.

In some embodiments, the first controller can be a central controller. That is, the first controller can control all the tray assemblies 14 and structural assemblies 12 corresponding to the tray assemblies 14. The first controller can be arranged at the chassis 11. When the first controller detects the leakage in the manual mode, the valve of the cooling pipeline 14a and the power source of the power supply circuit 14b of the tray assembly 14 that leaks can be shut off. Then, the cooling medium in the cooling pipeline of the tray assembly that leaks can stop circulation, and the leaking amount can be controlled. Meanwhile, the power supply to the tray assembly that leaks can be cut off. Thus, the cooling medium can be prevented from dripping onto the circuit to cause a short circuit to damage the electronic device.

In some embodiments, when the first controller is set to the automatic mode, after detecting the leakage, the first controller can directly control the structural assembly 12 corresponding to the tray assembly 14 that leaks to release the tray assembly 14 that leaks. When the tray assembly 14 is ejected, the tray assembly 14 can be disconnected from the power supply circuit 14b and the cooling circulation pipeline 14a. That is, after the tray assembly 14 is ejected, the power and the cooling medium can be automatically cut off. Thus, the first controller may not need to send the signal of cutting off the power and turning off the valve of the cooling circulation pipeline. To avoid the situation that the tray assembly 14 cannot be ejected smoothly due to increasing friction between the tray assembly and the chassis or other reasons, the first controller can be set to send the signal for cutting off the power and turning off the valve of the cooling circulation pipeline in the automatic mode.

In some embodiments, the leakage sensor 15 can include a first leakage sensor connected to the first controller and arranged around the chassis. A part of the first leakage sensor can be neighboring and opposite to each tray assembly 14. The first leakage sensor can be configured to detect whether each tray assembly arranged at the chassis 11 leaks. The physical feature of the first leakage sensor can be related to the leaking position.

FIG. 2 illustrates a schematic structural diagram of another water-cooling apparatus according to some embodiments of the present disclosure. The leakage sensor 15 in FIG. 1 is replaced by a leakage sensor 151. The leakage sensor 151 is arranged around the chassis 11 and connected to the first controller (not shown in the figure). The tray assembly 14 is arranged in the gap formed when the leakage sensor 151 is arranged around. That is, the leakage sensor 151 is arranged at the chassis around the tray assembly 14. When the leaking cooling medium drips onto the leakage sensor 151, since the leaking position is different, the resistance of the leakage sensor 151 can change. Based on the change in the value of the resistance, the first controller can determine which tray assembly leaks. The leakage sensor 151 and the first controller are arranged at the chassis. When the tray assembly 14 is ejected, the leakage sensor 151 and the first controller may not be ejected with the tray assembly 14.

With the above leakage sensor 151, the leakage detection can be directly performed on the plurality of tray assemblies 14, i.e., the overall server. The leakage sensor 151 can occupy a small space and may not need to be provided with additional power. Thus, the internal space of the server can be saved.

In some embodiments, the controller 13 can include a second controller configured to turn off the valve of the cooling circulation pipeline 14a of the tray assembly 14 that leaks and cuts off the power source of the power supply circuit 14b after the leakage is detected in the manual mode.

The second controller can be further configured to control the structural assembly 12 corresponding to the tray assembly 14 that leaks to release the tray assembly 14 that leaks after the leakage is detected in the automatic mode. The second controller can be arranged in the server node of the tray assembly 14.

In some embodiments, the second controller can be a sub-controller arranged at each tray assembly 14. That is, each second controller can only control the corresponding tray assembly 14. The second controller can be configured to turn off the valve of the cooling circulation pipeline 14a of the tray assembly 14 that leaks and cut off the power source of the power supply circuit 14b when the corresponding tray assembly 14 is detected to have leakage in the manual mode. The second controller can be configured to directly control the structural assembly 12 corresponding to the tray assembly 14 that leaks to release the tray assembly 14 that leaks after the corresponding tray assembly 14 is detected to have leakage in the automatic mode. The second controller can be integrated with the server node at the tray assembly 14, and the second controller can have an individual power supply and does not use the same power source as the tray assembly 14. When the tray assembly is ejected, the second controller can be ejected together with the tray assembly.

In some embodiments, the operation mode of the second controller can be set by the first controller or directly by maintenance personnel. The second controller at each tray assembly 14 can be individually set for the operation mode. A plurality of second controllers can be independent of each other. The second controller can issue a warning once the leakage is detected in any operation mode. The warning can include but is not limited to sending warning information to the maintenance personnel, the buzzer continuously sending an alarm.

By using the second controller, each tray assembly 14 can be controlled independently. The second controller can be powered with an independent power source. After the power of the tray assembly 14 is cut off, the second controller can still continuously send the alarm when the leakage of the tray assembly 14 is detected.

In some embodiments, the leakage sensor 15 can include a second leakage sensor connected to the second controller and arranged at a lower portion of each tray assembly. The second leakage sensor can be configured to detect whether the corresponding tray assembly leaks.

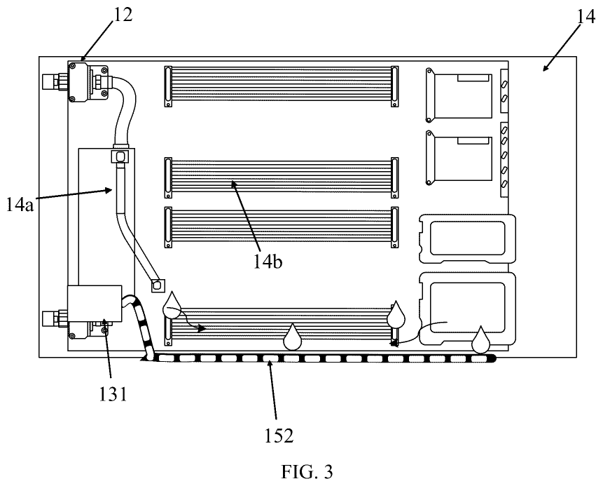

FIG. 3 illustrates a schematic structural diagram of another water-cooling apparatus according to some embodiments of the present disclosure.

In some embodiments, the leakage sensor 15 in FIG. 1 is replaced by a leakage sensor 152 in FIG. 3. The leakage sensor 152 is connected to the controller 131. The controller 31 can be the second controller. The leakage sensor 152 can be arranged under each tray assembly 14. The leakage sensor 152 can have the same detection principle as the above leakage sensor 151. The difference between the leakage sensor 152 and the leakage sensor 151 is that the length of the leakage sensor 151 is greater than the length of the leakage sensor 152. The leakage sensor 152 can be independently arranged for each tray assembly 14. When the tray assembly 14 is ejected, the leakage sensor 152 can be ejected together with the tray assembly 14.

In embodiments of the present disclosure, the first controller, the second controller, the first leakage sensor, and the second leakage sensor can be used in any combination. When the first controller and the second controller have different operation modes, the structural assembly 12 and the tray assembly 14 can execute the signal instruction issued by the second controller first.

Through the leakage sensor 152, each tray assembly 14 can be monitored independently to improve the accuracy of the leakage detection. When the leakage sensor 152 and the leakage sensor 151 are used together, the reliability of the leakage detection can be further improved.

In some embodiments, the tray assembly 14 can include a collection tray 141. The collection tray 141 can include a through-hole 141a in the middle position of the collection tray 141. The collection tray 141 can be arranged at the bottom of each tray assembly 14 and can be configured to collect the leaking cooling medium and guide to the chassis.

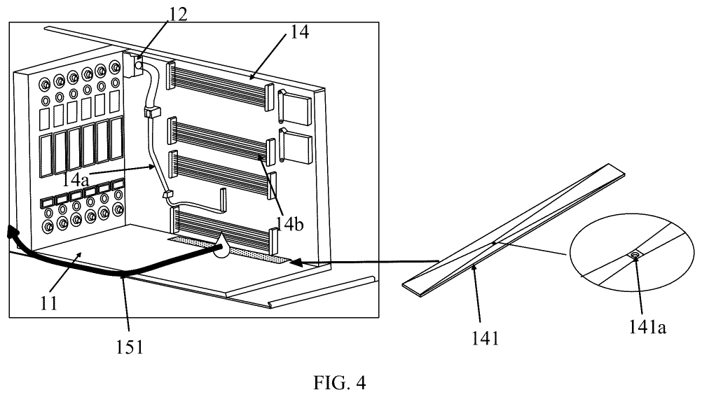

FIG. 4 illustrates a schematic structural diagram of another water-cooling apparatus according to some embodiments of the present disclosure.

In some embodiments, as shown in FIG. 4, the collection tray 141 is arranged under the tray assembly 14. Slopes are arranged on two sides of the collection tray 141. The height of the two sides can be higher than the middle portion. The slopes can be configured to guide the collected leaking liquid to the through-hole 141a in the middle. The leaking liquid can naturally flow to the leaking liquid collection tank (not shown in the figure) via the through-hole 141a.

In some embodiments, the leakage sensor 152 can be arranged at the collection tray 141, and the leakage sensor 151 can be arranged under the collection tray 141. The above assemblies can be arranged according to such sequence, since the leaking liquid gradually seeps to the bottom of the apparatus when the leakage is not severe, the severity of the leakage can be determined according to the time difference between the time when the leakage sensor 152 and the leakage sensor 151 detect the leakage when the tray assembly 14 leaks. If the time difference can be relatively small, the leakage is severe otherwise the leakage may not be severe.

In some embodiments, the structural assembly 12 can include an elastic assembly 121 arranged in front of each tray assembly 14 and configured to provide a pushing force to push the tray assembly 14 out after a baffle assembly 122 can be unlocked.

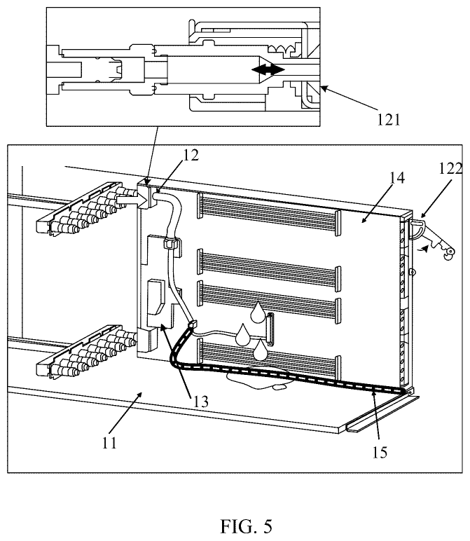

FIG. 5 illustrates a schematic structural diagram of another water-cooling apparatus according to some embodiments of the present disclosure.

In some embodiments, as shown in FIG. 5, the elastic assembly 121 includes an internal mechanical elastic mechanism. When the tray assembly is in a fixed state, the mechanical elastic structure inside the elastic assembly 121 is in a compressed state. Then, the elastic assembly 121 can have a push force for the tray assembly 14. However, due to the obstruction of the baffle assembly 122, the tray assembly 14 may not be pushed out. After the baffle assembly 122 is unlocked, the tray assembly can be pushed out by the pushing force of the elastic assembly 121. The elastic assembly 121 can be a pure mechanical elastic assembly without needing the power supply.

The tray assembly 14 can be pushed out when the tray assembly 14 leaks through the elastic assembly 121. When the tray assembly 14 is not properly mounted, the elastic assembly 121 can eject the tray assembly 14, which can avoid unreliable connections of the members on the tray assembly 14 when the tray assembly 14 is not properly mounted.

The baffle assembly 122 can be arranged at the rear side of each tray assembly 14 and can be configured to fix the baffle assembly 14 in the lock state.

The electromagnetic valve 123 can be grouped with the baffle assembly 14 and can be configured to control the baffle assembly 122 to be locked or unlocked.

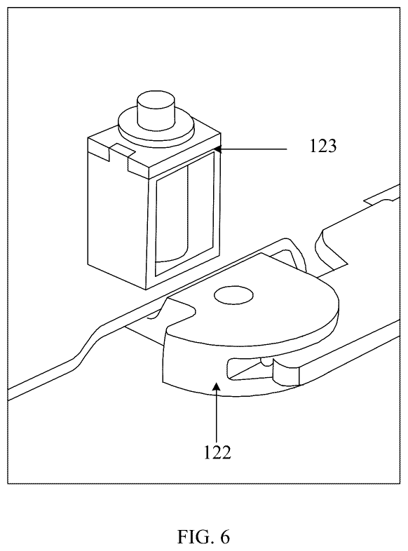

FIG. 6 illustrates a schematic structural diagram of a baffle assembly 14 and an electromagnetic valve 123 according to some embodiments of the present disclosure.

In some embodiments, the baffle assembly 122 can be grouped with the electromagnetic 123. When the baffle assembly is arranged in the state in FIG. 6, the portion of the baffle assembly 122 that is blocked can be fixed by the electromagnetic valve 123 to prevent the tray assembly 14 from being pushed out by the elastic assembly 121.

In some embodiments, the electromagnetic valve 123 can be in a lock state under a normal state. When the tray assembly 14 leaks, the controller 13 can send a signal to power on the electromagnetic valve 123. The electromagnetic valve 123 can be unlocked to lease the tray assembly 122. Meanwhile, the electromagnetic valve 123 can be unlocked by being powered on and can be also unlocked manually by the maintenance personnel. The specific unlocking method can be selected depending on the operation mode of the controller.

With the group of the baffle assembly 122 and the electromagnetic valve 123, the tray assembly can be reliably fixed, which allows the manual operation of the maintenance personnel to be more flexible.

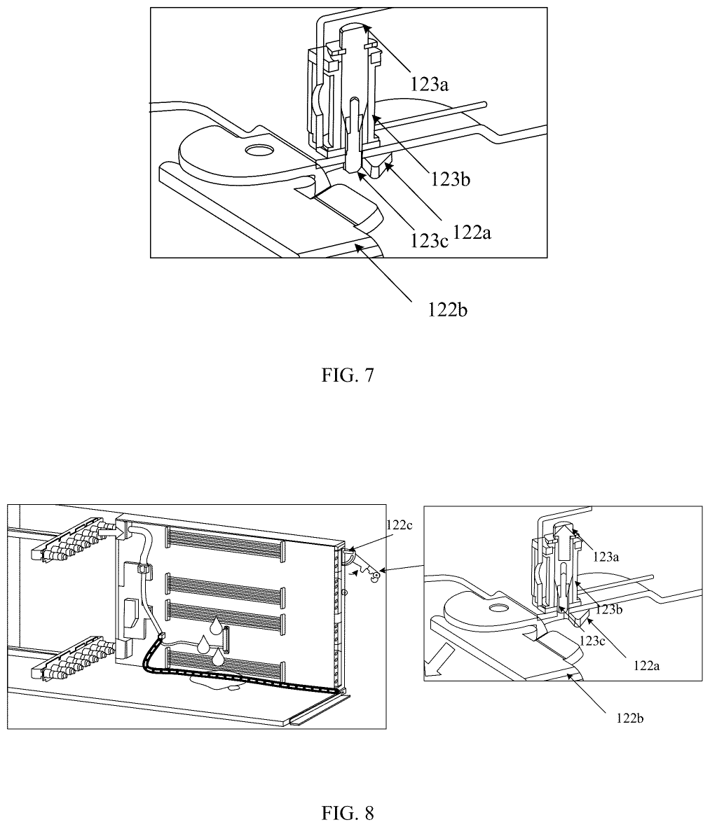

FIG. 7 illustrates a schematic structural diagram of an electromagnetic valve 123 according to some embodiments of the present disclosure. As shown in FIG. 7, an elastic force of a spring 123a pushes a latch 123c to move downward to lock the baffle assembly. After a solenoid 123b is powered on, the generated magnetic force can cause the latch 123c to move upward to unlock the electromagnetic valve to release the baffle assembly.

In some embodiments, the electromagnetic valve 123 can include a spring 123a configured to eject the latch 123c to cause the latch 123c to move downward when the solenoid 123b is not powered on. The solenoid 123b can be configured to cause the latch 123c to move upward after being powered on to unlock the baffle assembly. The latch 123c can be mounted inside the solenoid 123b and configured to lock the baffle assembly 122 when the solenoid 123b is not powered on.

In some embodiments, to cause the latch 123c to be able to move upward under the impact of the magnetic force, the latch 123c can be made of a metal material or at least partially made of the metal material. A metal material with a relatively low density can be used. Thus, the mass of the latch 123c can be reduced as much as possible to prevent the latch 123c from moving upward due to insufficient magnetic force. Meanwhile, when the solenoid 123b is powered on, a current as small as possible can be used when the latch 123c can be caused to move upward. The power source for the solenoid 123b can be the same power source for the tray assembly 14. In some embodiments, the magnitude of the magnetic force can be changed by adjusting the magnitude of the current to cooperate with the latches 123c with different masses. The tray assembly 14 can be powered off after being pushed out in the automatic mode. The tray assembly 14 being pushed out can indicate that the various portions of the electromagnetic valve 123 operate normally. After the tray assembly 14 is pushed out, no impact can be caused even if the solenoid 123b is powered off.

By using the electromagnetic valve 123, the mechanical mechanism can be grouped with the electromagnetic member to maintain the lock state of the electromagnetic valve through the mechanical structure without requiring a continuous power supply. Only when the electromagnetic valve needs to be unlocked, the electromagnetic valve can be powered to be unlocked by the magnetic force, which has relatively high reliability. Moreover, by selecting the latch 123c with a small mass, the requirement for the solenoid 123b may not be high, and the load may not be increased for the power supply of the tray assembly 14.

In some embodiments, the baffle assembly 122 can include a buckle 122a connected to the baffle through a shaft and can cooperate with the latch 123c to lock the baffle 122b. The buckle 122a can rotate around the shaft. The baffle assembly 122 can further include the baffle 122b configured to prevent the tray assembly 14 from being ejected when the buckle is locked. The baffle 122b can further include a protrusion structure, which can slide along the rail after the buckle 122a is unlocked. The baffle assembly 122 can further include a positioning plate 122c connected to another end of the baffle 122b, including a rail, and configured to limit the rotation of the baffle 122b around the rail after the buckle 122a is unlocked.

FIG. 8 illustrates a schematic structural diagram of another water-cooling apparatus according to some embodiments of the present disclosure, including a structural diagram of the baffle assembly.

In some embodiments, as shown in FIG. 8, the buckle 122a can cooperate with the latch 123c to lock. When the latch 123c moves downward, the protrusion of the buckle 122a can be blocked by the latch to lock the whole baffle assembly 122 to prevent the tray assembly from being pushed out.

In some embodiments, the baffle 122b can be connected to the buckle 122a through the shaft. The buckle 122a can rotate around the shaft to facilitate the maintenance personnel to manually unlock the baffle assembly 122 in the manual mode.

In some embodiments, the baffle assembly can further include a positioning plate 122c. The positioning plate 122c can be arranged at the end position of the baffle 122b and include an arch-shape through-hole. The baffle 122b can move along the arc-shape through-hole. Correspondingly, a corresponding protrusion structure (not shown in the figure) can be arranged at the end of the baffle 122b. The protrusion structure can slide in the arc-shape through-hole after the baffle 122b is grouped with the positioning plate 122c. Thus, the whole baffle 122b can move along a trajectory of the arc-shape through-hole.

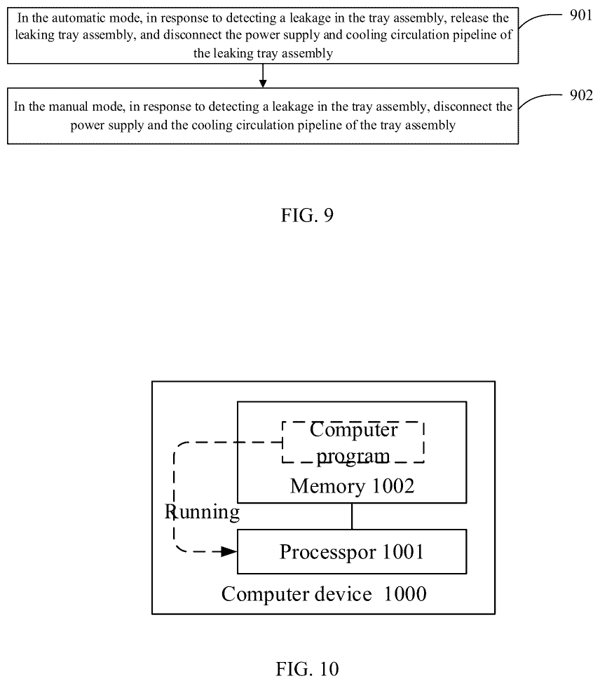

FIG. 9 illustrates a schematic flowchart of a leakage processing method according to some embodiments of the present disclosure. The method includes the following processes.

At 901, in the automatic mode, in response to detecting a leakage in the tray assembly 14, the leaking tray assembly 14 is released, and the power supply and cooling circulation pipeline of the leaking tray assembly 14 are disconnected.

In some embodiments, when a leakage occurs, the tray assembly 14 can be first released. Then, the power supply and the cooling circulation pipeline of the tray assembly 14 can be disconnected to avoid the situation that the tray assembly 14 is not able to be automatically ejected due to power loss. When the tray assembly 14 is pushed out, the power supply and the cooling medium circulation of the tray assembly 14 can be automatically disconnected.

At 902, in the manual mode, in response to detecting a leakage in the tray assembly 14, the power supply and the cooling circulation pipeline of the tray assembly 14 are disconnected.

In some embodiments, since interference may exist between members, directly ejecting the tray assembly 14 can damage the assembly. Thus, only the power supply and cooling medium circulation of the leaking tray assembly can be disconnected, and a warning can be issued without releasing the tray assembly, until the maintenance personnel manually take out the tray assembly for processing.

The description of the apparatus embodiments is similar to the description of the method embodiments and has a similar beneficial effect as the method embodiments. In some embodiments, the functions or modules of the apparatus of embodiments of the present disclosure can be used to implement the method described in method embodiments. For the technical details not provided in the apparatus embodiments, reference can be made to the description of the method embodiments.

In some embodiments, when the operation modes and methods are implemented by the software functional modules and are sold or used as an individual product, the software functional modules can be stored in the computer-readable storage medium. Based on such understanding, the technical solution or the part contributing to the related technology of embodiments of the present disclosure can be implemented by a software product. The software product can be stored in a storage medium and include several instructions to cause the computer device (e.g., a personal computer, a server, or a network device) to execute all or a part of the method of embodiments of the present disclosure. The storage medium can include a U drive, a portable hard drive, read-only memory (ROM), magnetic disks, optical disks, or other media that can store program codes. Thus, embodiments of the present disclosure are not limited to any specific hardware, software, or firmware, or any combination thereof.

Embodiments of the present disclosure further provide a computer device including a memory and a processor. The memory can store a computer program running on the processor. The processor can execute the program to implement a part or all of the steps of the method above.

Embodiments of the present disclosure further provide a computer-readable storage medium storing the computer program that, when executed by the processor, causes the processor to implement a part or all of the steps of the method above. The computer-readable storage medium can be volatile or non-volatile.

Embodiments of the present disclosure further provide a computer program including computer codes. When the computer-readable codes are running in the computer device, the processor of the computer device can be configured to implement a part or all of the steps of the method above.

Embodiments of the present disclosure provide a computer program product. The computer program product can include a non-volatile computer-readable storage medium storing the computer program. When the computer program is read and executed by the computer, a part or all of the steps of the method can be implemented. The computer program product can be implemented by hardware, software, or a combination thereof. In some embodiments, the computer program product can be a computer storage medium. In some other embodiments, the computer program product can be a software product, e.g., a software development kit (SDK), etc.

The description of embodiments of the present disclosure tends to highlight the differences between embodiments of the present disclosure, and same or similar parts can be referred to each other. The description of the device, storage medium, computer program, and computer program product are similar to the description of the method embodiments and has similar beneficial effect as the method embodiments. For the technical details not described in embodiments of the device, storage medium, computer program, and computer program product of the present disclosure, reference can be made to the description of the method embodiments.

FIG. 10 illustrates a schematic diagram of a hardware entity of a computer device 1000 according to some embodiments of the present disclosure. As shown in FIG. 10, the hardware entity of the computer device 1000 includes a processor 1001 and a memory 1002. The memory 1002 stores a computer program that runs on the processor 1001. When the processor 1001 executes the program, the steps of the method of any embodiments of the present disclosure can be implemented.

The memory 1002 can store the computer program that runs on the processor. The memory 1002 can be configured to store instructions and applications executable by the processor 1001. The memory 1002 can cache to-be-processed or processed data by the processor 1001 and modules of the computer device 1000 (e.g., image data, audio data, voice communication data, and video communication data), which can be implemented by Flash or random-access memory (RAM).

When the processor 1001 executes the program, the steps of any one updating method for the operation mode. The processor 1001 can generally control the overall operation of the computer device 1000.

Embodiments of the present disclosure provide a computer storage medium. The computer storage medium can store one or more programs. The one or more programs can be executed by one or more processors to implement the steps of the updating method for the operation mode of any one of the embodiments above.

The description of the storage medium and device embodiments is similar to the description of the method embodiments and has a similar beneficial effect. For the technical details not described in the storage medium and device embodiments, reference can be made to the description of the method embodiments of the present disclosure.

The processor above can include at least one of an Application-Specific Integrated Circuit (ASIC), a Digital Signal Processor (DSP), a Digital Signal Processing Device (DSPD), a Programmable Logic Device (PLD), a Field Programmable Gate Array (FPGA), a Central Processing Unit (CPU), a controller, a microcontroller, or a microprocessor. The device implementing the processor functions can include other devices, which is not limited in embodiments of the present disclosure.

The computer storage medium/memory above can include Read-Only Memory (ROM), Programmable Read-Only Memory (PROM), Erasable Programmable Read-Only Memory (EPROM), Electrically Erasable Programmable Read-Only Memory (EEPROM), Ferromagnetic Random Access Memory (FRAM), Flash Memory, magnetic surface memory, optical disk, or Compact Disc Read-Only Memory (CD-ROM), or various terminals including one of the above memories, such as a cellphone, a computer, a tablet device, or a personal digital assistant.

The term “one embodiment” or “an embodiment” mentioned throughout the specification mean that features, structures, or characteristics related to the embodiment are at least included in at least one embodiment of the present disclosure. Thus, the term “one embodiment” or “an embodiment” mentioned throughout the specification does not necessarily refer to the same embodiment. In addition, these specific features, structures, or characteristics can be combined in any suitable manner in one or more embodiments. In embodiments of the present disclosure, the numerical orders of the steps/processes above do not indicate the execution sequence. The execution sequence of the steps/processes can be determined by the functions and internal logic of the steps/processes, which do not limit the implementation process of embodiments of the present disclosure. The number of embodiments of the present disclosure are merely used for description and does not imply relative importance.

In the specification, the terms “comprise,” “include,” or any other variations of the terms are intended to cover non-exclusive inclusion. Thus, a process, method, article, or device that includes a series of elements not only includes those elements but can also include other elements not explicitly listed, or elements inherent to such process, method, article, or device. Without further limitations, an element defined by the phrase “comprising a . . . ” does not exclude the presence of other identical elements in the process, method, article, or device that comprises the element.

In embodiments of the present disclosure, the disclosed device and method can be implemented in other methods. The described device embodiments are merely illustrative. For example, the division of the unit can be a logical functional division, and in practical applications, the unit can be divided in other methods. For example, a plurality of units or assemblies can be combined or integrated into another system, or some features can be ignored or may not be executed. In addition, the couplings, direct couplings, or communication connections among members shown or discussed can be indirect couplings or communication connections through some interfaces, devices, or units, which can be electrical, mechanical, or other forms.

The units described as separate members above may or may not be physically separated. The members shown as units may or may not be physical units, which can be located in one place or distributed across a plurality of network units. Some or all of the units can be selected as needed to implement the purposes of embodiments of the present disclosure.

In addition, the functional units of embodiments of the present disclosure can be integrated into a processing unit, or each unit can be independently used as a unit. In some embodiments, two or more units can also be integrated into a unit. The integrated unit can be implemented in hardware or as a combination of hardware and software functional units. Those skilled in the art can understand that all or a part of the steps of the methods embodiments can be implemented by hardware related to the program instructions. The program can be stored in a computer-readable storage medium. When the program is executed, the steps of the method embodiments can be executed. The storage medium above can include mobile storage devices, Read-Only Memory (ROM), magnetic disks, optical discs, or various media capable of storing program codes.

In some other embodiments, when integrated units are implemented by software functional modules and sold or used as an individual product, the integrated units can be stored in a computer-readable storage medium. The essence of the technical solution of the present disclosure or the part of the technical solution of the present disclosure contributing to the related technology can be embedded in a software product. The computer software product can be stored in a storage medium and include several instructions to cause the computer device (e.g., a personal computer, a server, or a network device) to execute all or a part of the method of embodiments of the present disclosure. The storage medium can include a medium storing program code, such as a mobile storage device, ROM, magnetic disc, or optical disc.

The above description is merely some embodiments of the present disclosure. However, the scope of the present disclosure is not limited to this. Those skilled in the art can easily think of modifications or replacements within the scope of the present disclosure, which are within the scope of the present disclosure.

What is claimed is:

1. A water-cooling apparatus comprising:
a chassis configured to accommodate at least one tray assembly, power and cooling medium circulation being supplied to the tray assembly through a power supply circuit and a cooling circulation pipeline;
a structure assembly arranged on a front side and a rear side of the tray assembly and configured to fix or release the tray assembly, a direction in which the tray assembly slides after being released being the rear side, the front side being opposite the rear side, a power source of the power supply circuit and a valve of the cooling circulation pipeline of the tray assembly being turned off after being released by the structure assembly;
a controller connected to the structure assembly and a leakage sensor and configured to issue a signal based on a predetermined operation mode after the leakage sensor detects a leakage;
the tray assembly configured to accommodate a fixed server node and vertically arranged at the chassis; and
the leakage sensor connected to the controller, arranged at the chassis and/or the tray assembly to be neighboring to the tray assembly, and configured to detect whether the tray assembly leaks.

2. The apparatus according to claim 1, wherein the controller includes a first controller configured to:
determine the tray assembly that leaks based on the leakage sensor;
turn off the valve of the cooling circulation pipeline and the power source of the power supply circuit of the tray assembly that leaks in response to detecting the leakage in a manual mode; and
control the structural assembly corresponding to the tray assembly that leaks to release the tray assembly that leaks in response to detecting the leakage in an automatic mode.

3. The apparatus according to claim 2, wherein the leakage sensor includes:
a first leakage sensor connected to the first controller, arranged around the chassis, and partially adjacent and opposite to each tray assembly, and configured to detect whether each tray assembly mounted at the chassis leaks, and a physical characteristic of the first leakage sensor being related to a position where the leakage occurs.

4. The apparatus according to claim 1, wherein the controller includes a second controller arranged in the server node of the tray assembly and configured to:
turn off the valve of the cooling circulation pipeline and the power source of the power supply circuit for the leaking tray assembly after the leakage is detected in a manual mode; and
control the structure assembly corresponding to the leaking tray assembly to release the leaking tray assembly after the leakage is detected in an automatic mode.

5. The apparatus according to claim 4, wherein the leakage sensor includes a second leakage sensor connected to the second controller, arranged at a lower part of each tray assembly, and configured to detect whether the corresponding tray assembly leaks.

6. The apparatus according to claim 1, wherein the tray assembly includes:
a collection tray including a through-hole in a middle position, arranged at bottom of each tray assembly, and configured to collect and guide a leaking cooling medium to the chassis.

7. The apparatus according to claim 1, wherein the structure assembly includes:
an elastic assembly arranged on the front side of each tray assembly and configured to provide a push force to push out the tray assembly after the baffle assembly is unlocked;
the baffle assembly arranged on the rear side of each tray assembly and configured to fix the tray assembly in the lock status; and
an electro-magnetic valve grouped with the baffle assembly and configured to control the baffle assembly to be locked or unlocked.

8. The apparatus according to claim 7, wherein the electro-magnetic valve includes:
a spring configured to eject a latch to cause the latch to move downward when a solenoid is not powered on;
the solenoid configured to cause the latch to move upward after being powered on to unlock the baffle assembly; and
the latch arranged in the solenoid and configured to lock the baffle assembly when the solenoid is not powered on.

9. The apparatus according to claim 7, wherein the baffle assembly includes:
a buckle connected to a baffle through a rotation shaft, configured to cooperate with the latch to lock the baffle, and rotate around the shaft;
the baffle configured to prevent the tray assembly from being ejected when the buckle is locked and including a protrusion structure sliding along a rail after being unlocked; and
a positioning plate connected to another end of the baffle and including a rail configured to limit the baffle to rotate along the rail after the buckle is unlocked.

10. A leakage processing method comprising:
in an automatic mode, in response to detecting that a tray assembly leaks, releasing the leaking tray assembly and disconnecting power supply and a cooling circulation pipeline of the leaking tray assembly; and
in a manual mode, in response to detecting that the tray assembly leaks, disconnecting the power supply and the cooling circulation pipeline of the leaking tray assembly.

11. The method according to claim 10, further comprising:
determining the tray assembly that leaks based on the leakage sensor;
turning off the valve of the cooling circulation pipeline and the power source of the power supply circuit of the tray assembly that leaks in response to detecting the leakage in a manual mode; and
controlling the structural assembly corresponding to the tray assembly that leaks to release the tray assembly that leaks in response to detecting the leakage in an automatic mode.

12. The method according to claim 11, further comprising:
detecting whether each tray assembly mounted at the chassis leaks, and a physical characteristic of the first leakage sensor being related to a position where the leakage occurs.

13. The method according to claim 10, further comprising:
turning off the valve of the cooling circulation pipeline and the power source of the power supply circuit for the leaking tray assembly after the leakage is detected in a manual mode; and
controlling the structure assembly corresponding to the leaking tray assembly to release the leaking tray assembly after the leakage is detected in an automatic mode.

14. The method according to claim 13, further comprising:
detecting whether the corresponding tray assembly leaks.

15. The method according to claim 10, further comprising:
collecting and guiding a leaking cooling medium to the chassis.

16. The method according to claim 10, further comprising:
providing a push force, by an elastic assembly, to push out the tray assembly after the baffle assembly is unlocked;
fixing the tray assembly, by a baffle assembly, in the lock status; and
controlling the baffle assembly to be locked or unlocked.

17. The method according to claim 16, further comprising:
ejecting a latch to cause the latch to move downward when a solenoid is not powered on;
causing the latch to move upward after being powered on to unlock the baffle assembly; and
locking the baffle assembly when the solenoid is not powered on.

18. The method according to claim 16, further comprising:
cooperating with the latch to lock the baffle, and rotate around the shaft;
preventing the tray assembly from being ejected when the buckle is locked and including a protrusion structure sliding along a rail after being unlocked; and
limiting the baffle to rotate along the rail after the buckle is unlocked.
